(19) United States
(12) Patent Application Publication
(10) Pub. No.: US 2024/0099152 A1
(43) Pub. Date: Mar. 21, 2024

(54) MAGNETO RESISTIVE ELEMENT

(71) Applicant: TDK CORPORATION, Tokyo (JP)

(72) Inventors: Kazuumi INUBUSHI, Tokyo (JP); Katsuyuki NAKADA, Tokyo (JP); Shinto ICHIKAWA, Tokyo (JP)

(73) Assignee: TDK CORPORATION, Tokyo (JP)

(21) Appl. No.: 17/945,738

(22) Filed: Sep. 15, 2022

(51) Int. Cl. H01L 43/08; G11C 11/16; H01L 27/22; H01L 43/02

(52) U.S. Cl. CPC H01L 43/08; G11C 11/161; H01L 27/222; H01L 43/02

(57) ABSTRACT

A magneto resistive element includes a first ferromagnetic layer, a second ferromagnetic layer, a nonmagnetic layer, and a buffer layer. The nonmagnetic layer is between the first ferromagnetic layer and second ferromagnetic layer. The buffer layer is in contact with the first ferromagnetic layer. The first ferromagnetic layer contains a Heusler alloy containing Co. The buffer layer contains at least a first atom, a second atom, and a third atom other than Co as main components. The buffer layer does not contain Co or contains Co at a proportion less than a compositional proportion of the first atom, the second atom, and the third atom. In a case where an atomic radius of any one atom of the first atom, the second atom, and the third atom is taken as a reference, an atomic radius of another atom thereof is 95% or less or 105% or more of the reference.

### FIELD

### Background

The present disclosure relates to a magneto resistive element.

### Description of Related Art

A magneto resistive element is an element whose resistance value in a stacking direction changes due to a magnetoresistance effect. A magneto resistive element includes two ferromagnetic layers and a nonmagnetic layer interposed therebetween. A magneto resistive element using a conductor for a nonmagnetic layer is referred to as a giant magneto resistive (GMR) element, and a magneto resistive element using an insulating layer (a tunnel barrier layer or barrier layer) for a nonmagnetic layer is referred to as a tunnel magneto resistive (TMR) element. A magneto resistive element can be applied in various applications such as a magnetic sensor, a high frequency component, a magnetic head, and a magnetic random access memory (MRAM).

U.S. Pat. No. 9,412,399 describes a magnetic sensor including a magneto resistive element using a Heusler alloy for a ferromagnetic layer. The Heusler alloy has a high spin polarization. A magnetic sensor including a Heusler alloy is expected to have a large output signal. Further, U.S. Pat. No. 9,412,399 describes that a Heusler alloy is less likely to crystallize unless a film of the Heusler alloy is formed at a high temperature or a film of the Heusler alloy is formed on a thick base substrate having predetermined crystallinity. Such processing can cause a decrease in the output of the magnetic sensor.

### SUMMARY

The magnitude of the output signal of the magnetic sensor depends on a magnetoresistance ratio (an MR ratio) of the magneto resistive element. In general, the higher the crystallinity of the ferromagnetic layers with the nonmagnetic layer interposed therebetween, the higher the MR ratio tends to be. There is a demand for a configuration that allows the Heusler alloy to easily crystallize without using the high-temperature film formation or the thick base substrate having predetermined crystallinity.

This magneto resistive element includes a first ferromagnetic layer, a second ferromagnetic layer, a nonmagnetic layer, and a buffer layer. The nonmagnetic layer is between the first ferromagnetic layer and the second ferromagnetic layer. The buffer layer is in contact with the first ferromagnetic layer. The first ferromagnetic layer contains a Heusler alloy containing Co. The buffer layer contains at least a first atom, a second atom, and a third atom other than Co as main components. The buffer layer does not contain Co or contains Co at a proportion less than a compositional proportion of the first atom, the second atom, and the third atom. In a case where an atomic radius of any one atom of the first atom, the second atom, and the third atom is taken as a reference, an atomic radius of another atom thereof is 95% or less or 105% or more of the reference.

### BRIEF DESCRIPTION OF THE DRAWINGS

FIG. 1 is a cross-sectional view of a magneto resistive element according to a first embodiment.

FIG. 2A is a view showing a crystal structure of a Heusler alloy.

FIG. 2B is a view showing a crystal structure of a Heusler alloy.

FIG. 2C is a view showing a crystal structure of a Heusler alloy.

FIG. 2D is a view showing a crystal structure of a Heusler alloy.

FIG. 2E is a view showing a crystal structure of a Heusler alloy.

FIG. 2F is a view showing a crystal structure of a Heusler alloy.

FIG. 3 is a cross-sectional view of a magneto resistive element according to a second embodiment.

FIG. 4 is a cross-sectional view of a magnetic recording element according to Application Example 1.

FIG. 5 is a cross-sectional view of a magnetic recording element according to Application Example 2.

FIG. 6 is a cross-sectional view of a magnetic recording element according to Application Example 3.

FIG. 7 is a cross-sectional view of a high frequency device according to Application Example 4.

### DETAILED DESCRIPTION

Hereinafter, the present embodiment will be described in detail with appropriate reference to the drawings. In the drawings used in the following description, feature portions may be enlarged for convenience to make the features of the present embodiment easy to understand, and dimensional ratios of each constituent element and the like may be different from the actual ones. Materials, dimensions, and the like exemplified in the following description are examples, and the present invention is not limited thereto and can be appropriately modified and carried out within the scope in which the gist of the present invention is not changed.

### First Embodiment

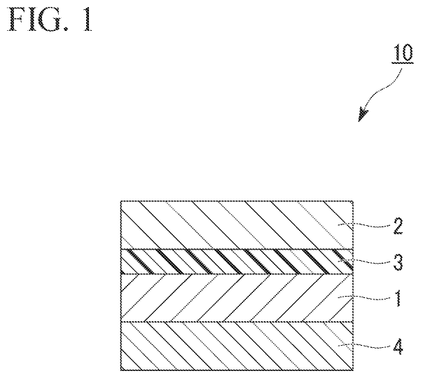

FIG. 1 is a cross-sectional view of a magneto resistive element according to a first embodiment. First, directions will be defined. A direction in which layers are stacked may be referred to as a stacking direction. Further, a direction which intersects with the stacking direction and in which each layer extends may be referred to as an in-plane direction.

The magneto resistive element 10 shown in FIG. 1 includes a first ferromagnetic layer 1, a second ferromagnetic layer 2, a nonmagnetic layer 3, and a buffer layer 4.

The magneto resistive element 10 outputs a change in relative angle between magnetization of the first ferromagnetic layer 1 and magnetization of the second ferromagnetic layer 2 as a change in resistance value. The magnetization of the second ferromagnetic layer 2 is, for example, easier to move than the magnetization of the first ferromagnetic layer 1. In a case where a predetermined external force is applied, a magnetization direction of the first ferromagnetic layer 1 does not change (is fixed), and a magnetization direction of the second ferromagnetic layer 2 changes. As the magnetization direction of the second ferromagnetic layer 2 changes with respect to the magnetization direction of the first ferromagnetic layer 1, the resistance value of the magneto resistive element 10 changes. In this case, the first ferromagnetic layer 1 may be referred to as a magnetization fixed layer, and the second ferromagnetic layer 2 may be referred to as a magnetization free layer. Hereinafter, the first ferromagnetic layer 1 will be described as a magnetization fixed layer, and the second ferromagnetic layer 2 will be described as a magnetization free layer, but this relationship may be reversed.

A difference in easiness of movement between the magnetization of the first ferromagnetic layer 1 and the magnetization of the second ferromagnetic layer 2 when a predetermined external force is applied is caused by a difference in coercivity between the first ferromagnetic layer 1 and the second ferromagnetic layer 2. For example, when a thickness of the second ferromagnetic layer 2 is smaller than a thickness of the first ferromagnetic layer 1, the coercivity of the second ferromagnetic layer 2 may often be smaller than the coercivity of the first ferromagnetic layer 1. Further, for example, an antiferromagnetic layer may be disposed on a surface of the first ferromagnetic layer 1 opposite to a side of the nonmagnetic layer 3 via a spacer layer. The first ferromagnetic layer 1, the spacer layer, and the antiferromagnetic layer form a synthetic antiferromagnetic structure (an SAF structure). The synthetic antiferromagnetic structure is constituted by two magnetic layers with a spacer layer interposed therebetween. When antiferromagnetic coupling is performed between the first ferromagnetic layer 1 and the antiferromagnetic layer, a coercivity of the first ferromagnetic layer 1 becomes larger than a case where the antiferromagnetic layer is not provided and the antiferromagnetic coupling is not performed. The antiferromagnetic layer is formed of, for example, IrMn, PtMn, or the like. The spacer layer contains, for example, at least one selected from the group consisting of Ru, Jr, and Rh.

The first ferromagnetic layer contains, for example, a Heusler alloy containing Co. At least a part of the Heusler alloy is crystallized. The Heusler alloy may be wholly crystallized, for example.

Whether or not the Heusler alloy is crystallized can be determined with a transmission electron microscope (TEM) image (for example, a high-angle scattering annular dark field scanning transmission microscope image: an HAADF-STEM image) or an electron beam diffraction image using a transmission electron beam. When the Heusler alloy is crystallized, for example, it is possible to check in the HAADF-STEM image that atoms are arranged regularly. More specifically, a spot derived from a crystal structure of the Heusler alloy appears in a Fourier transform image of the HAADF-STEM image. Further, when the Heusler alloy is crystallized, a diffraction spot can be checked from at least one plane of a (001) plane, a (002) plane, a (110) plane, a (111) plane, and a (011) plane in the electron beam diffraction image. In a case where crystallization can be checked by at least any means, it can be said that at least a part of the Heusler alloy is crystallized.

In the Heusler alloy, crystals are mainly oriented (or preferentially oriented) in a (001) or (011) direction, for example. Being mainly oriented in the (001) or (011) direction means that a main crystal direction of the crystals forming the Heusler alloy is the (001) or (011) direction. For example, in a case where the Heusler alloy is formed of a plurality of crystal grains, crystal directions of the crystal grains may differ. In this case, when a direction of a synthetic vector of a crystal orientation direction in 50 arbitrary crystal grains is within a range of inclination of 25° or less with respect to the (001) direction, it can be said that the crystals are mainly oriented in the (001) direction. The same applies to the (011) direction. The Heusler alloy in which the orientation directions of the constituent crystals are aligned has high crystallinity, and an MR ratio of the magneto resistive element 10 including this Heusler alloy is high. Further, an orientation direction that is considered to be equivalent to the (001) direction is also included in a (001) orientation. That is, the (001) orientation includes a (001) orientation, a (010) orientation, a (100) orientation, and all orientation directions opposite thereto.

A Heusler alloy is an intermetallic compound with an XYZ or X₂YZ chemical composition. A ferromagnetic Heusler alloy represented by X₂YZ is referred to as a full-Heusler alloy, and a ferromagnetic Heusler alloy represented by XYZ is referred to as a half-Heusler alloy. The half-Heusler alloy is obtained by making some of X-site atoms in the full-Heusler alloy vacant.

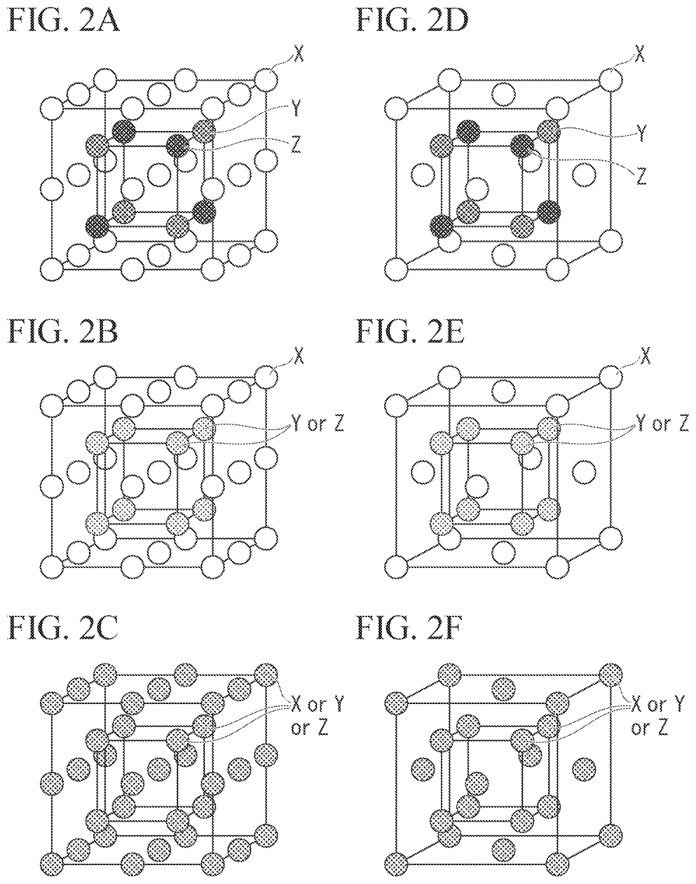

FIGS. 2A to 2F show examples of the crystal structure of the Heusler alloy. FIGS. 2A, 2B, and 2C are examples of the crystal structure of the full-Heusler alloy, and FIGS. 2D, 2E, and 2F are examples of the crystal structure of the half-Heusler alloy.

FIG. 2A is referred to as an L2₁ structure. In the L2₁ structure, an element entering an X site, an element entering a Y site, and an element entering a Z site are fixed. FIG. 2B is referred to as a B2 structure derived from the L2₁ structure. In the B2 structure, an element entering a Y site and an element entering a Z site are mixed with each other, and an element entering an X site is fixed. FIG. 2C is referred to as an A2 structure derived from the L2₁ structure. In the A2 structure, an element entering an X site, an element entering a Y site, and an element entering a Z site are mixed with each other.

FIG. 2D is referred to as a C1_{b} structure. In the C1_{b} structure, an element entering an X site, an element entering a Y site, and an element entering a Z site are fixed. FIG. 2E is referred to as a B2 structure derived from the C1_{b} structure. In the B2 structure, an element entering a Y site and an element entering a Z site are mixed with each other, and an element entering an X site is fixed. FIG. 2F is referred to as an A2 structure derived from the C1_{b} structure. In the A2 structure, an element entering an X site, an element entering a Y site, and an element entering a Z site are mixed with each other.

Crystallinity of the full-Heusler alloy is higher in the order of L2₁ structure >B2 structure >A2 structure, and crystallinity of the half-Heusler alloy is higher in the order of C1_{b} structure >B2 structure >A2 structure. All of these crystal structures are crystals, although they differ in crystallinity. The first ferromagnetic layer 1 has, for example, any of the crystal structures described above. The crystal structure of the first ferromagnetic layer 1 is, for example, the L2₁ structure or the B2 structure.

Here, X is a transition metal element or noble metal element from the Co, Fe, Ni, or Cu group in the periodic table, Y is a transition metal element from the Mn, V, Cr, or Ti group in the periodic table or the same type of element as for X, and Z is a typical element from Groups III to V in the periodic table. In a case where the Heusler alloy contains Co, X is Co.

The Heusler alloy containing Co is represented by, for example, Co₂Y_{α}Z_{β}. Y is, for example, one or more elements selected from the group consisting of Fe, Mn, and Cr. Z is, for example, one or more elements selected from the group consisting of Si, Al, Ga, and Ge. α+β>2 is satisfied. Y is particularly preferably Fe, and Z is particularly preferably Ga and Ge. For example, α satisfies 0.3<α<2.1 and more preferably satisfies 0.4<α<2.0. β satisfies 0.1≤β≤2.0.

The full-Heusler alloy in stoichiometric composition is represented by Co₂YZ. When α+β>2 is satisfied, the Co compositional proportion becomes relatively smaller than the sum of the compositional proportions of the elements on the Y site and the Z site. When the Co compositional proportion is relatively smaller than the sum of the compositional proportions of the Y-site and Z-site elements, it is possible to avoid an anti-site in which the Y-site and Z-site elements are substituted with the X-site element (Co). The anti-site shifts a Fermi level of the Heusler alloy. When the Fermi level shifts, a half-metallicity of the Heusler alloy decreases, and a spin polarization of the Heusler alloy decreases. A decrease in spin polarization causes a decrease in the MR ratio of the magneto resistive element 10.

The Heusler alloy containing Co may be represented by, for example, Co₂Fe_{α}Ga_{β1}G_{β}2. In the composition formula, α+β1+β2≥2.3, α<β1+β2, 0.5<α<1.9, 0.1≤β1, and 0.1≤β2 may be satisfied.

The full-Heusler alloy containing Co is, for example, Co₂FeSi, Co₂FeAl, Co₂FeGeₓGa₁₋ₓ, Co₂MnGeₓGa₁₋ₓ, Co₂MnSi, Co₂MnGe, Co₂MnGa, Co₂MnSn, Co₂MnAl, Co₂CrAl, Co₂VAl, Co₂Mn₁₋ₐFeₐAl_{b}Si_{1-b}, or the like. The half-Heusler alloy containing Co is represented by, for example, CoFeSb and CoMnSb.

The second ferromagnetic layer 2 may be a Heusler alloy or a ferromagnetic layer other than a Heusler alloy. In a case where the second ferromagnetic layer 2 contains a Heusler alloy, the same material as the first ferromagnetic layer 1 can be used. In a case where the second ferromagnetic layer 2 is a ferromagnetic layer other than a Heusler alloy, the second ferromagnetic layer 2 contains, for example, a metal selected from the group consisting of Cr, Mn, Co, Fe, and Ni, an alloy containing one or more of these metals, or an alloy containing these metals and at least one element of B, C, and N. The second ferromagnetic layer 2 is, for example, Co—Fe or Co—Fe—B.

The nonmagnetic layer 3 is interposed between the first ferromagnetic layer 1 and the second ferromagnetic layer 2. The nonmagnetic layer 3 has a thickness, for example, within a range of 1 nm or more and 10 nm or less. The nonmagnetic layer 3 inhibits magnetic coupling between the first ferromagnetic layer 1 and the second ferromagnetic layer 2.

The nonmagnetic layer 3 is made of, for example, a nonmagnetic metal. The nonmagnetic layer 3 is formed of, for example, a metal or alloy containing any element selected from the group consisting of Cu, Au, Ag, Al, and Cr. The metal or alloy containing these elements is excellent in electrical conductivity and reduces the resistance area product (hereinafter referred to as RA) of the magneto resistive element 10. The nonmagnetic layer 3 contains, for example, any element selected from the group consisting of Cu, Au, Ag, Al, and Cr as a main constituent element. Cu, Au, Ag, Al, or Cr being included as the main constituent element means that its proportion in the composition formula is 50% or more. The nonmagnetic layer 3 preferably contains Ag and preferably contains Ag as the main constituent element. Since Ag has a long spin diffusion length, the magneto resistive element 10 using Ag shows a high MR ratio.

The nonmagnetic layer 3 may be an insulator or a semiconductor. The nonmagnetic insulator is, for example, Al₂O₃, SiO₂, MgO, MgAl₂O₄, or a material in which a part of Al, Si, or Mg is replaced with Zn, Be, or the like. These materials have a large bandgap and excellent insulating properties. In a case in which the nonmagnetic layer 3 is made of the nonmagnetic insulator, the nonmagnetic layer 3 is a tunnel barrier layer. The nonmagnetic semiconductor is, for example, Si, Ge, CuInSe₂, CuGaSe₂, Cu(In, Ga)Se₂, or the like.

The buffer layer 4 is in contact with the first ferromagnetic layer 1. When the magneto resistive element 10 includes the buffer layer 4, the first ferromagnetic layer 1 is easily crystallized when the magneto resistive element 10 is manufactured. The buffer layer 4 is amorphous immediately after film formation. The buffer layer 4 after annealing may be amorphous or have a crystal structure.

The buffer layer 4 contains at least a first atom, a second atom, and a third atom as main components. The buffer layer 4 contains three or more kinds of atoms as the main components. The atoms that are the main components of the buffer layer 4 are atoms intentionally added during manufacturing. In a case where the buffer layer 4 has crystallinity, the atoms that are the main components are responsible for the crystal structure. The atoms that are the main components have, for example, a compositional proportion (a molar proportion) of 5 at % or more. The first atom, the second atom, and the third atom are atoms other than Co.

The composition of each layer can be determined using energy dispersive X-ray spectroscopy (EDS). Further, by performing the EDS, for example, the composition distribution of each material in a film thickness direction can be checked.

In a case where an atomic radius of any one atom of the first atom, the second atom, and the third atom is taken as a reference, an atomic radius of another atom thereof is 95% or less or 105% or more of the reference. For example, when an atomic radius of the first atom is taken as a reference, an atomic radius of the second atom is 95% or less or 105% or more of the atomic radius of the first atom, and an atomic radius of the third atom is 95% or less or 105% or more of the atomic radius of the first atom. For example, when an atomic radius of the second atom is taken as a reference, an atomic radius of the first atom is 95% or less or 105% or more of the atomic radius of the second atom, and an atomic radius of the third atom is 95% or less or 105% or more of the atomic radius of the second atom. For example, when an atomic radius of the third atom is taken as a reference, an atomic radius of the first atom is 95% or less or 105% or more of the atomic radius of the third atom, and an atomic radius of the second atom is 95% or less or 105% or more of the atomic radius of the third atom.

In a case where an atomic radius of any one atom of the first atom, the second atom, and the third atom is taken as a reference, an atomic radius of another atom thereof is preferably 90% or less or 110% or more of the reference and more preferably 85% or less or 115% or more of the reference.

When the buffer layer 4 contains three or more types of atoms that satisfy the above conditions, the buffer layer 4 becomes amorphous immediately after film formation. When the buffer layer 4 is amorphous immediately after film formation, it is possible to curb an influence of the buffer layer 4 on the crystal structure of the first ferromagnetic layer 1 when the adjacent first ferromagnetic layer 1 is crystallized by annealing.

The buffer layer 4 may not contain Co or may contain a small amount of Co. Even in a case where Co is not intentionally added to the buffer layer 4, Co may enter the buffer layer 4 by diffusion from the first ferromagnetic layer 1 or the like during manufacturing, for example. In a case where the buffer layer 4 contains Co, the compositional proportion of Co is less than a compositional proportion of the first ferromagnetic layer 1, preferably less than a compositional proportion of any one of the first atom, the second atom, and the third atom, and more preferably is 5 at % or less.

When a concentration of Co contained in the buffer layer 4 is low, it is possible to curb that Co diffuses from the buffer layer 4 into the first ferromagnetic layer 1 during annealing and the anti-site in which the Y-site and Z-site elements are substituted with Co occurs.

In a case where the buffer layer 4 contains Co, a Co concentration at a center of the buffer layer 4 in a thickness direction is lower than a Co concentration at an interface between the buffer layer 4 and the first ferromagnetic layer 1, for example. The Co concentration may decrease toward the center of the buffer layer 4 in the thickness direction from the interface between the buffer layer 4 and the first ferromagnetic layer 1, for example.

The first atom, the second atom, and the third atom are, for example, nonmagnetic atoms. When the first atom, the second atom, and the third atom are nonmagnetic atoms, it is possible to curb that the buffer layer 4 and the first ferromagnetic layer 1 are magnetically coupled to each other and the magnetization state of the first ferromagnetic layer 1 is disturbed. When the magnetization state of the first ferromagnetic layer 1 is stabilized, the MR ratio of the magneto resistive element 10 increases.

Further, the first atom, the second atom, and the third atom may be different from atoms constituting the Heusler alloy, for example. When this configuration is satisfied, it is possible to curb atomic diffusion between the first ferromagnetic layer 1 and the buffer layer 4.

Further, any one of the first atom, the second atom, and the third atom is a transition metal atom or a metalloid atom. The metalloid atom is, for example, boron, silicon, germanium, arsenic, antimony, tellurium, polonium, or astatine. For example, the first atom may be a transition metal atom, the second atom may be a metalloid atom, and the third atom may be an arbitrary atom. In this case, the molar proportion of the first atom is preferably 15 at % or more and 30 at % or less. Further, for example, the first atom may be a transition metal atom, the second atom may be a transition metal atom which is different from the first atom, and the third atom may be an arbitrary atom. When the above configuration is satisfied, the buffer layer 4 is amorphous immediately after film formation to be stabilized.

Further, the first atom, the second atom, and the third atom are at different positions in the periodic table. When the configuration is satisfied, the buffer layer 4 is amorphous immediately after film formation to be stabilized. For example, the first atom, the second atom, and the third atom belong to different periods in the periodic table. For example, the first atom, the second atom, and the third atom belong to different groups in the periodic table. Further, for example, the first atom may belong to any one of Group 4, Group 5, and Group 6 in the periodic table, the second atom may belong to Group 11 in the periodic table, and the third atom may belong to Group 13 or Group 14 in the periodic table.

Examples of a specific combination of the first atom, the second atom, and the third atom include a combination of Fe, B, and Ta, a combination of Fe, Si, and Ru, a combination of Cr, Ge, and Mo, a combination of Cr, Si, and Mo, a combination of Cr, Si, and Zr, a combination of Au, Si, and Ti, a combination of Au, Si, and Zr, and a combination of Au, B, and Zr.

A thickness of the buffer layer 4 is, for example, 1 nm or less. The thickness of the buffer layer 4 is, for example, 10 Å or more and 90 Å or less.

The magneto resistive element 10 may have a layer other than the first ferromagnetic layer 1, the second ferromagnetic layer 2, the nonmagnetic layer 3, and the buffer layer 4 described above. For example, a surface of the buffer layer 4 opposite to the first ferromagnetic layer 1 may have a base layer, and a surface of the second ferromagnetic layer 2 opposite to the nonmagnetic layer 3 may have a cap layer. The base layer and the cap layer enhance the crystal orientation of the first ferromagnetic layer 1 and the second ferromagnetic layer 2. The base layer and the cap layer each contain, for example, Ru, Ir, Ta, Ti, Al, Au, Ag, Pt, or Cu. Further, as a layer for enhancing lattice matching, a NiAl layer may be provided between the first ferromagnetic layer 1 and the nonmagnetic layer 3 or between the second ferromagnetic layer 2 and the nonmagnetic layer 3.

Next, a method of manufacturing the magneto resistive element 10 will be described. First, a substrate that serves as a base for film formation is prepared. The substrate may be crystalline or amorphous. Examples of a crystalline substrate include metal oxide single crystals, silicon single crystals, and sapphire single crystals. Examples of an amorphous substrate include silicon single crystals with a thermal oxide film, glass, ceramics, and quartz.

Next, the base layer is formed on the substrate as needed. The base layer may be a stacked film of a plurality of layers. Each layer is formed by a sputtering method, for example. Next, the buffer layer 4 is formed on the base layer. The buffer layer 4 is formed by a sputtering method, for example. The buffer layer 4 is less likely to crystallize because the buffer layer 4 has the first atom, the second atom, and the third atom which have different atomic radius as described above. Therefore, the buffer layer 4 becomes amorphous immediately after film formation.

Next, the first ferromagnetic layer 1 is formed on the buffer layer 4. Since the buffer layer 4 is amorphous, the first ferromagnetic layer 1 is formed without being affected by the crystal structure of the buffer layer 4.

Next, the nonmagnetic layer 3 and the second ferromagnetic layer 2 are formed on the first ferromagnetic layer 1 in that order. The nonmagnetic layer 3 and the second ferromagnetic layer 2 can be formed by a sputtering method.

Next, the stacked body stacked on the substrate is annealed. The temperature for annealing is, for example, 300° C. or less and is, for example, 250° C. or more and 300° C. or less.

When the stacked body is annealed, the first ferromagnetic layer 1 and the second ferromagnetic layer 2 are crystallized. Since the buffer layer 4 is amorphous before annealing, the first ferromagnetic layer 1 is less likely to be affected by the buffer layer 4 when the first ferromagnetic layer 1 is crystallized. Therefore, the first ferromagnetic layer 1 is crystallized even at a low annealing temperature. Since the annealing is performed, the first ferromagnetic layer 1 and the second ferromagnetic layer 2 are crystallized. The buffer layer 4 may be crystallized after annealing or may remain amorphous.

Here, the above method has been introduced as one of processes of the method of manufacturing the magneto resistive element 10, but the above method can also be applied to a method of crystallizing a ferromagnetic layer. For example, a Heusler alloy having crystallinity can be obtained by stacking a ferromagnetic layer containing a Heusler alloy on the amorphous buffer layer 4 and heating them.

In the method of manufacturing the magneto resistive element 10 according to the present embodiment, the first ferromagnetic layer 1 and the second ferromagnetic layer 2 are crystallized at a low temperature of 300° C. or less. If the temperature is 300° C. or less, even though the annealing is performed after other constituent elements of the magnetic head are manufactured, for example, adverse effects on the other constituent elements (for example, a magnetic shield) can be reduced. Therefore, the timing of annealing is not restricted, and the manufacturing of elements such as magnetic heads is facilitated.

Further, in the magneto resistive element 10 according to the present embodiment, the first ferromagnetic layer 1 and the second ferromagnetic layer 2 with the nonmagnetic layer 3 interposed therebetween are crystallized. Therefore, the first ferromagnetic layer 1 and the second ferromagnetic layer 2 show high spin polarization. As a result, the magneto resistive element 10 according to the present embodiment shows a high MR ratio.

### Second Embodiment

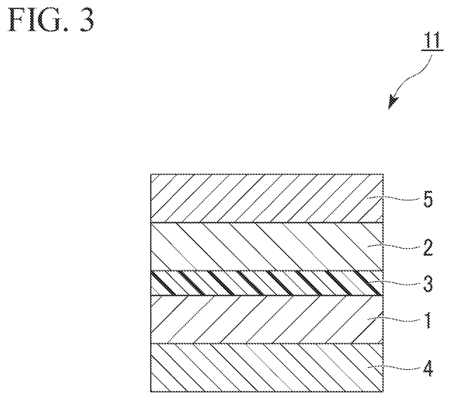

FIG. 3 is a cross-sectional view of a magneto resistive element 11 according to a second embodiment. The magneto resistive element 11 has a first ferromagnetic layer 1, a second ferromagnetic layer 2, a nonmagnetic layer 3, the buffer layer 4, and a buffer layer 5. The magneto resistive element 11 differs from the magneto resistive element 10 according to the first embodiment in that it has the buffer layer 5. In the magneto resistive element 11 according to the second embodiment, the same constituent elements as those of the magneto resistive element 10 according to the first embodiment are designated by the same reference signs, and the description thereof will be omitted.

In the magneto resistive element 11, the second ferromagnetic layer 2 contains a Heusler alloy. The Heusler alloy contained in the second ferromagnetic layer 2 is the same as that of the first ferromagnetic layer 1 and is a Heusler alloy containing Co. The buffer layer 5 is in contact with the second ferromagnetic layer 2. The buffer layer 5 is amorphous immediately after film formation. The buffer layer 5 after annealing may be amorphous or have a crystal structure.

The buffer layer 5 is the same as the buffer layer 4. The buffer layer 5 contains at least a first atom, a second atom, and a third atom as main components. The buffer layer 5 contains three or more kinds of atoms as the main components.

The buffer layer 5 may not contain Co or may contain a small amount of Co. In a case where the buffer layer 5 contains Co, the compositional proportion of Co is less than a compositional proportion of the second ferromagnetic layer 2, preferably less than a compositional proportion of any one of the first atom, the second atom, and the third atom, and more preferably is 5 at % or less.

In a case where the buffer layer 5 contains Co, a Co concentration at a center of the buffer layer 5 in a thickness direction is lower than a Co concentration at an interface between the buffer layer 5 and the second ferromagnetic layer 2, for example. The Co concentration may decrease toward the center of the buffer layer 5 in the thickness direction from the interface between the buffer layer 5 and the second ferromagnetic layer 2, for example.

The buffer layer 5 can be formed on the second ferromagnetic layer 2 by a sputtering method or the like. The buffer layer 5 is amorphous after film formation. The magneto resistive element 11 is obtained by annealing the stacked body after forming the buffer layer 5. The buffer layer 5 may be crystallized after annealing or may remain amorphous.

In the magneto resistive element 11 according to the second embodiment, the same effect as the magneto resistive element 10 according to the first embodiment is exhibited.

As described above, the embodiments have been described in detail with reference to the drawings, but the constituent elements and a combination of these of the embodiment are examples, and addition, omission, replacement, and other changes in configuration can be made without departing from the spirit of the present invention.

The magneto resistive element 10 described above can be used for various purposes. The magneto resistive element 10 can be applied to, for example, a magnetic head, a magnetic sensor, a magnetic memory, a high frequency filter, and the like. Next, application examples of the magneto resistive element according to the present embodiment will be described. In the application examples below, the magneto resistive element 10 is used, but the magneto resistive element is not limited to this.

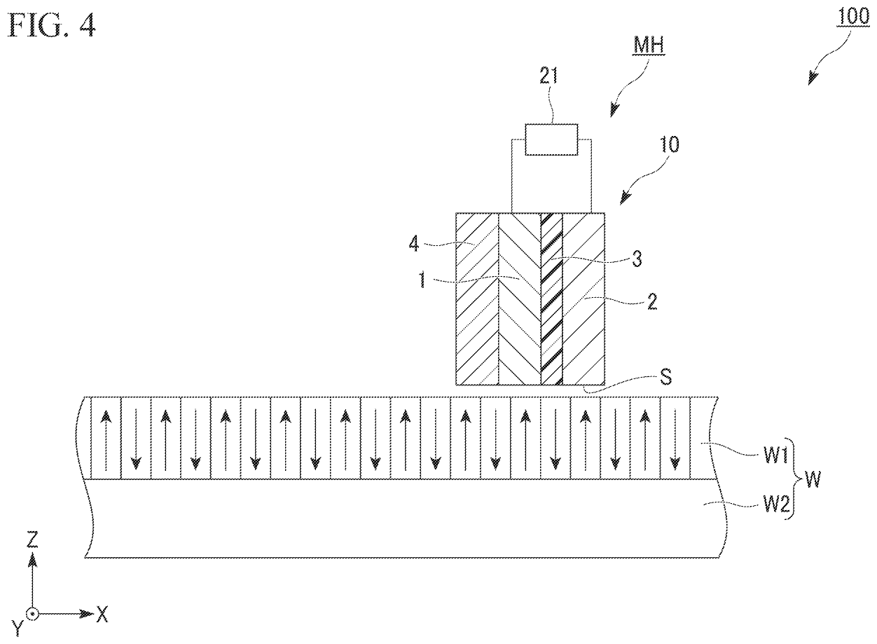

FIG. 4 is a cross-sectional view of a magnetic recording element 100 according to Application Example 1. FIG. 4 is a cross-sectional view of the magneto resistive element 10 in the stacking direction.

As shown in FIG. 4, the magnetic recording element 100 has a magnetic head MH and a magnetic recording medium W. In FIG. 4, one direction in which the magnetic recording medium W extends is defined as an X direction, and a direction perpendicular to the X direction is defined as a Y direction. An XY plane is parallel to a main surface of the magnetic recording medium W. A direction in which the magnetic recording medium W and the magnetic head MH are connected to each other and which is perpendicular to the XY plane is defined as a Z direction.

The magnetic head MH has an air bearing surface (a medium facing surface) S that faces a surface of the magnetic recording medium W. The magnetic head MH moves along the surface of the magnetic recording medium W in directions of arrows+X and −X at a position away from the magnetic recording medium W by a certain distance. The magnetic head MH has the magneto resistive element 10 serving as a magnetic sensor and a magnetic recording part (not shown). A resistance measuring device 21 measures a resistance value of the magneto resistive element 10 in the stacking direction.

The magnetic recording part applies a magnetic field to a recording layer W1 of the magnetic recording medium W to determine a magnetization direction of the recording layer W1. That is, the magnetic recording part performs magnetic recording on the magnetic recording medium W. The magneto resistive element 10 reads magnetization information of the recording layer W1 which is written by the magnetic recording part.

The magnetic recording medium W has a recording layer W1 and a backing layer W2. The recording layer W1 is a portion for performing magnetic recording, and the backing layer W2 is a magnetic path (a path of a magnetic flux) for returning a magnetic flux for writing back to the magnetic head MH. The recording layer W1 records magnetic information in the magnetization direction.

The first ferromagnetic layer 1 of the magneto resistive element 10 is, for example, a magnetization fixed layer, and the magnetization direction is fixed in a +Z direction. The second ferromagnetic layer 2 of the magneto resistive element 10 is, for example, a magnetization free layer. Therefore, the second ferromagnetic layer 2 exposed on the air bearing surface S is affected by the magnetization recorded in the recording layer W1 of the facing magnetic recording medium W. For example, in FIG. 4, the magnetization direction of the second ferromagnetic layer 2 is oriented in a +Z direction under the influence of the +Z direction magnetization of the recording layer W1. In this case, the magnetization directions of the first ferromagnetic layer 1 and the second ferromagnetic layer 2, which are magnetization fixed layers, are in parallel.

Here, the resistance in a case where the magnetization directions of the first ferromagnetic layer 1 and the second ferromagnetic layer 2 are in parallel and the resistance in a case where the magnetization directions of the first ferromagnetic layer 1 and the second ferromagnetic layer 2 are in anti-parallel are different from each other. The MR ratio of the magneto resistive element 10 increases as the difference between the resistance value in the parallel case and the resistance value in the anti-parallel case increases. The magneto resistive element 10 according to the present embodiment contains a crystallized Heusler alloy and has a high MR ratio. Therefore, the magnetization information of the recording layer W1 can be accurately read as a resistance value change by the resistance measuring device 21.

The shape of the magneto resistive element 10 of the magnetic head MH is not particularly limited. For example, the first ferromagnetic layer 1 may be placed at a position away from the magnetic recording medium W in order to avoid the influence of the leakage magnetic field of the magnetic recording medium W on the first ferromagnetic layer 1 of the magneto resistive element 10.

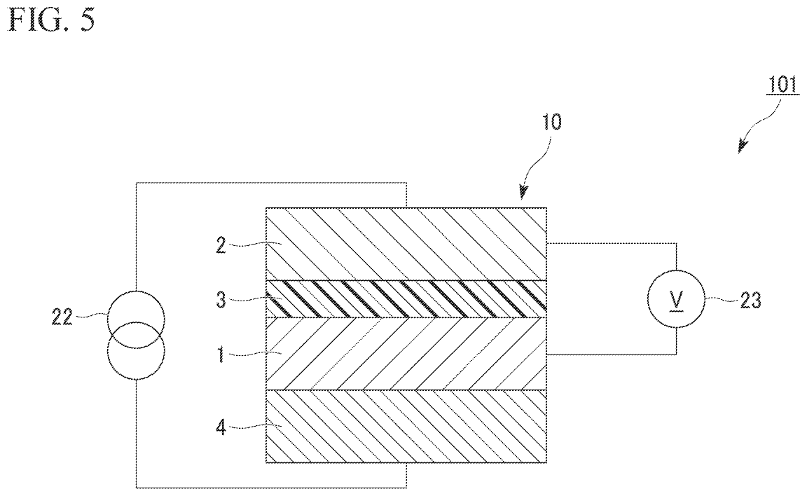

FIG. 5 is a cross-sectional view of a magnetic recording element 101 according to Application Example 2. FIG. 5 is a cross-sectional view of the magnetic recording element 101 in the stacking direction.

As shown in FIG. 5, the magnetic recording element 101 has the magneto resistive element 10, a power supply 22, and a measuring part 23. A power supply 22 applies a potential difference in the stacking direction of the magneto resistive element 10. The power supply 22 is, for example, a DC power supply. The measuring part 23 measures a resistance value of the magneto resistive element 10 in the stacking direction.

When the potential difference is generated between the first ferromagnetic layer 1 and the second ferromagnetic layer 2 by the power supply 22, a current flows in the stacking direction of the magneto resistive element 10. The current is spin-polarized when passing through the first ferromagnetic layer 1 and becomes a spin-polarized current. The spin-polarized current reaches the second ferromagnetic layer 2 through the nonmagnetic layer 3. The second ferromagnetic layer 2 receives a spin transfer torque (STT) due to the spin-polarized current and is subjected to magnetization reversal. As a relative angle between the magnetization direction of the first ferromagnetic layer 1 and the magnetization direction of the second ferromagnetic layer 2 changes, the resistance value of the magneto resistive element 10 in the stacking direction changes. The resistance value of the magneto resistive element 10 in the stacking direction is read by the measuring part 23. That is, the magnetic recording element 101 shown in FIG. 5 is a spin transfer torque (STT) type magnetic recording element.

Since the magnetic recording element 101 shown in FIG. 5 includes the magneto resistive element 10 containing a crystallized Heusler alloy and having a high MR ratio, the magnetic recording element 101 can accurately record data.

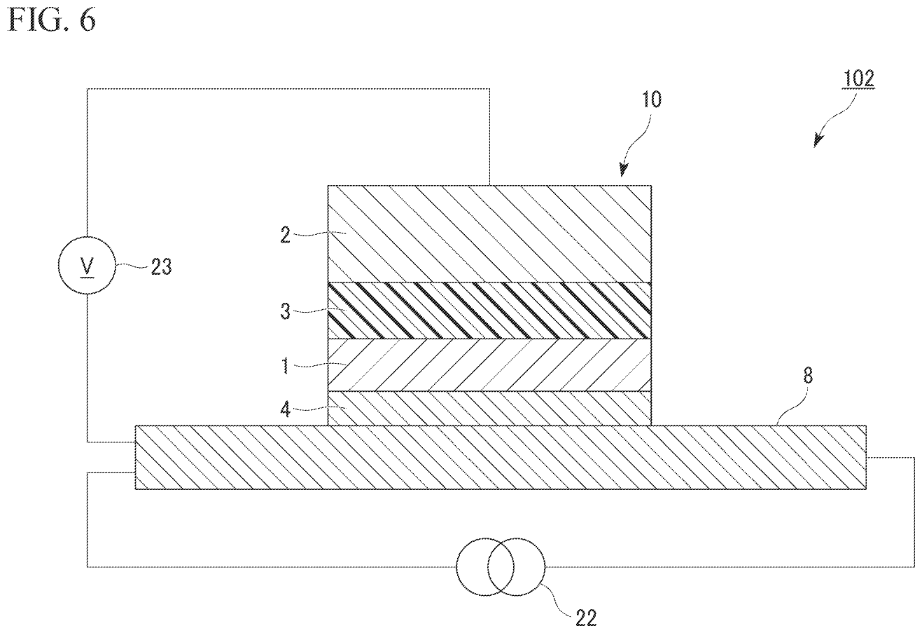

FIG. 6 is a cross-sectional view of a magnetic recording element 102 according to Application Example 3. FIG. 6 is a cross-sectional view of the magnetic recording element 102 in the stacking direction.

As shown in FIG. 6, the magnetic recording element 102 has the magneto resistive element 10, a spin-orbit torque wiring 8, a power supply 22, and a measuring part 23.

The spin-orbit torque wiring 8 is in contact with the first ferromagnetic layer 1 via the buffer layer 4, for example. The spin-orbit torque wiring 8 extends in one direction in the in-plane direction. In Application Example 3, the first ferromagnetic layer 1 is a magnetization free layer, and the second ferromagnetic layer 2 is a magnetization fixed layer. The thickness of the buffer layer 4 is equal to or less than a spin diffusion length of a material constituting the buffer layer, for example.

The power supply 22 is connected to a first end and a second end of the spin-orbit torque wiring 8. The magneto resistive element 10 is interposed between the first end and the second end in a plan view. The power supply 22 causes a write current to flow along the spin-orbit torque wiring 8. The measuring part 23 measures a resistance value of the magneto resistive element 10 in the stacking direction.

When a potential difference is generated between the first end and the second end of the spin-orbit torque wiring 8 by the power supply 22, a current flows in the in-plane direction of the spin-orbit torque wiring 8. The spin-orbit torque wiring 8 has a function of generating a spin current due to a spin Hall effect occurring when a current flows. The spin-orbit torque wiring 8 contains, for example, any one of a metal, an alloy, an intermetallic compound, a metal boride, a metal carbide, a metal silicide, and a metal phosphate which have a function of generating a spin current due to a spin Hall effect occurring when a current flows. For example, the wiring includes a nonmagnetic metal having a d-electron or an f-electron in the outermost shell and having an atomic number equal to or more than 39.

When a current flows in the in-plane direction of the spin-orbit torque wiring 8, the spin-orbit interaction causes a spin Hall effect. The spin Hall effect is a phenomenon in which spins are curb in a direction orthogonal to a flow direction of the current. The spin Hall effect causes uneven distribution of the spins in the spin-orbit torque wiring 8 and induces a spin current in a thickness direction of the spin-orbit torque wiring 8. The spins are injected into the first ferromagnetic layer 1 from the spin-orbit torque wiring 8 with the spin current.

Due to the spins injected into the first ferromagnetic layer 1, a spin-orbital torque (SOT) is applied to the magnetization of the first ferromagnetic layer 1. The first ferromagnetic layer 1 receives a spin-orbit torque (SOT) and is subjected to magnetization reversal. As a relative angle between the magnetization direction of the first ferromagnetic layer 1 and the magnetization direction of the second ferromagnetic layer 2 changes, the resistance value of the magneto resistive element 10 in the stacking direction changes. The resistance value of the magneto resistive element 10 in the stacking direction is read by the measuring part 23. That is, the magnetic recording element 102 shown in FIG. 6 is a spin-orbit torque (SOT) type magnetic recording element.

Since the magnetic recording element 102 shown in FIG. 6 includes the magneto resistive element 10 containing a crystallized Heusler alloy and having a high MR ratio, the magnetic recording element 102 can accurately record data.

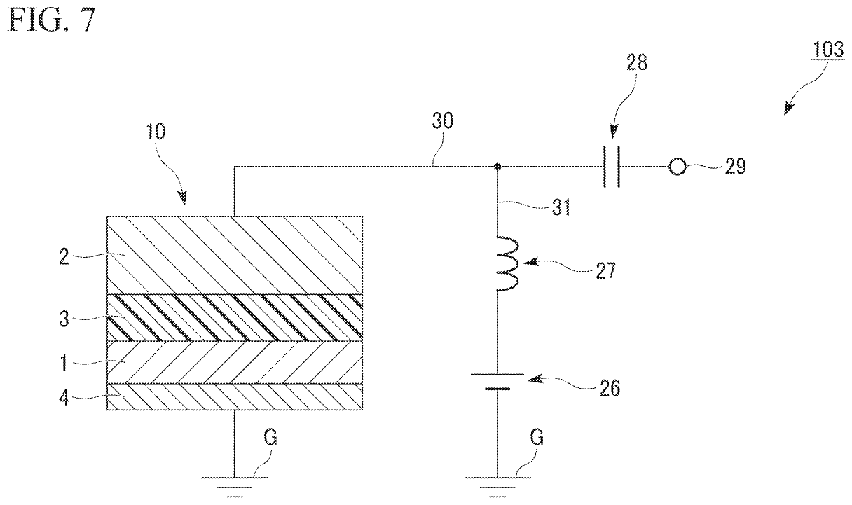

FIG. 7 is a schematic view of a high frequency device 103 according to Application Example 4. As shown in FIG. 7, the high frequency device 103 has the magneto resistive element 10, a DC power supply 26, an inductor 27, a capacitor 28, an output port 29, and wirings 30 and 31.

The wiring 30 connects the magneto resistive element 10 and the output port 29 to each other. The wiring 31 branches off from the wiring 30 and reaches a ground G via the inductor 27 and the DC power supply 26. As the DC power supply 26, the inductor 27, and the capacitor 28, known ones can be used. The inductor 27 cuts a high frequency component of a current and passes an invariant component of the current. The capacitor 28 passes the high frequency component of the current and cuts the invariant component of the current. The inductor 27 is arranged in a portion where it is desired to curb the flow of a high frequency current, and the capacitor 28 is arranged in a portion where it is desired to curb the flow of a direct current.

When an alternating current or alternating magnetic field is applied to the ferromagnetic layer included in the magneto resistive element 10, the magnetization of the second ferromagnetic layer 2 processes. The magnetization of the second ferromagnetic layer 2 strongly oscillates in a case when the frequency of the high frequency current or high frequency magnetic field applied to the second ferromagnetic layer 2 is in the vicinity of a ferromagnetic resonance frequency of the second ferromagnetic layer 2 and does not oscillate much at a frequency far from the ferromagnetic resonance frequency of the second ferromagnetic layer 2. This phenomenon is called a ferromagnetic resonance phenomenon.

The resistance value of the magneto resistive element 10 changes according to the oscillation of the magnetization of the second ferromagnetic layer 2. The DC power supply 26 applies a DC current to the magneto resistive element 10. The DC current flows in the stacking direction of the magneto resistive element 10. The direct current flows to the ground G through the wirings 30 and 31 and the magneto resistive element 10. The potential of the magneto resistive element 10 changes according to Ohm's law. A high frequency signal is output from the output port 29 according to the change in potential (a change in resistance value) of the magneto resistive element 10.

Since the high frequency device 103 shown in FIG. 7 includes the magneto resistive element 10 containing a crystallized Heusler alloy and having a wide range of the change in resistance value, the high frequency device 103 can transmit a high-output high frequency signal.

### EXAMPLES

### Example 1

As Example 1, the magneto resistive element 10 shown in FIG. 1 was manufactured. First, films of Cr and Ag were formed in that order as the base layer on a silicon substrate. Next, the buffer layer 4 was formed on the base layer. The buffer layer 4 was manufactured by sputtering Fe, Si, Ru, and Co at the same time. The buffer layer 4 contains Fe, Si, and Ru. The atomic radius of Fe is 124 Å, the atomic radius of Si is 114 Å, and the atomic radius of Ru is 136 Å. The buffer layer 4 contains Co, and the compositional proportion of Co was 5 at %. The thickness of the buffer layer 4 was 2 nm. Immediately after film formation, the buffer layer 4 was amorphous.

Next, the first ferromagnetic layer 1 was formed on the buffer layer 4. At that time point, the first ferromagnetic layer 1 was amorphous. The first ferromagnetic layer 1 is a Heusler alloy represented by Co₂Fe_{0.9}Ga_{0.5}Ge_{0.9}. The thickness of the first ferromagnetic layer 1 was 6 nm.

Next, the nonmagnetic layer 3 was formed on the first ferromagnetic layer 1. The nonmagnetic layer 3 is Ag. The thickness of the nonmagnetic layer 3 was 5 nm.

Next, the second ferromagnetic layer 2 was formed on the nonmagnetic layer 3. The first ferromagnetic layer 1 is a Heusler alloy represented by Co₂Fe_{0.9}Ga_{0.5}Ge_{0.9}. The thickness of the second ferromagnetic layer 2 was 4 nm.

Next, a film of Ta was formed as the cap layer on the second ferromagnetic layer 2. Then, the stacked body was annealed. Annealing was performed at 270° C. for 5 hours. Due to the annealing, the first ferromagnetic layer 1 and the second ferromagnetic layer 2 were crystallized.

The MR ratio of the manufactured magneto resistive element 10 was measured. As for the MR ratio, a change in resistance value of the magneto resistive element 10 was measured by monitoring a voltage applied to the magneto resistive element 10 with a voltmeter while sweeping a magnetic field from the outside to the magneto resistive element 10 with a constant current flowing in the stacking direction of the magneto resistive element. The resistance value in a case where the magnetization directions of the first ferromagnetic layer 1 and the second ferromagnetic layer 2 are in parallel and the resistance value in a case where the magnetization directions of the first ferromagnetic layer 1 and the second ferromagnetic layer 2 are in anti-parallel were measured, and the MR ratio was calculated from the obtained resistance values by the following formula. The measurement of the MR ratio was performed at 300K (a room temperature).

MR ratio (%)=(R_{AP}−R_{P})/R_{P}×100

R_{P} is the resistance value in a case where the magnetization directions of the first ferromagnetic layer 1 and the second ferromagnetic layer 2 are in parallel, and R_{AP} is the resistance value in a case where the magnetization directions of the first ferromagnetic layer 1 and the second ferromagnetic layer 2 are in anti-parallel.

The MR ratio of the magneto resistive element 10 according to Example 1 was 9.1%.

### Example 2

Example 2 differs from Example 1 in that there is a distribution in the concentration of Co contained in the buffer layer 4. The Co concentration at the interface between the first ferromagnetic layer 1 and the buffer layer 4 was higher than the Co concentration at the center of the buffer layer 4 in the thickness direction. The Co concentration distribution in the buffer layer 4 was formed by continuously decreasing the film formation power of Co when the buffer layer 4 was formed. The MR ratio of the magneto resistive element 10 according to Example 2 was 10.5%.

### Examples 3 to 8

Examples 3 to 8 differ from Example 1 in that the atoms forming the buffer layer were changed. Other conditions were the same as in Example 1.

The buffer layer 4 of Example 3 contains Cr, Ge, and Mo. Cr, Ge, and Mo are all nonmagnetic atoms. The atomic radius of Cr is 130 Å, the atomic radius of Ge is 120 Å, and the atomic radius of Mo is 146 Å. The MR ratio of the magneto resistive element 10 according to Example 3 was 14.3%.

The buffer layer 4 of Example 4 contains Cr, Si, and Mo. Cr, Si, and Mo are all nonmagnetic atoms and belong to different periods. Si is a metalloid atom. The atomic radius of Cr is 130 Å, the atomic radius of Si is 114 Å, and the atomic radius of Mo is 146 Å. The MR ratio of the magneto resistive element 10 according to Example 4 was 15.5%.

The buffer layer 4 of Example 5 contains Cr, Si, and Zr. Cr, Si, and Zr are all nonmagnetic atoms and belong to different periods and groups. Si is a metalloid atom. The atomic radius of Cr is 130 Å, the atomic radius of Si is 114 Å, and the atomic radius of Zr is 164 Å. The MR ratio of the magneto resistive element 10 according to Example was 17.0%.

The buffer layer 4 of Example 6 contains Au, Si, and Ti. Au, Si, and Ti are all nonmagnetic atoms and belong to different periods and groups. Au belongs to Group 11, Si belongs to Group 14, and Ti belongs to Group 4. Si is a metalloid atom. The atomic radius of Au is 130 Å, the atomic radius of Si is 114 Å, and the atomic radius of Ti is 148 Å. The MR ratio of the magneto resistive element 10 according to Example 6 was 19.6%.

The buffer layer 4 of Example 7 contains Au, Si, and Zr. Au, Si, and Zr are all nonmagnetic atoms and belong to different periods and groups. Au belongs to Group 11, Si belongs to Group 14, and Zr belongs to Group 4. Si is a metalloid atom. The atomic radius of Au is 130 Å, the atomic radius of Si is 114 Å, and the atomic radius of Zr is 164 Å. The MR ratio of the magneto resistive element 10 according to Example 7 was 21.1%.

The buffer layer 4 of Example 8 contains Au, B, and Zr. Au, B, and Zr are all nonmagnetic atoms and belong to different periods and groups. Au belongs to Group 11, B belongs to Group 13, and Zr belongs to Group 4. Si is a metalloid atom. The atomic radius of Au is 130 Å, the atomic radius of B is 84 Å, and the atomic radius of Zr is 164 Å. The MR ratio of the magneto resistive element 10 according to Example 8 was 23.4%.

### Comparative Examples 1 and 2

Comparative Examples 1 and 2 differ from Example 1 in that the atoms forming the buffer layer were changed. Other conditions were the same as in Example 1. The buffer layer 4 of Comparative Example 1 contains Co, Fe, B, and Ta as main components. The buffer layer 4 contains Co as the main component, and the compositional proportion of Co was 37 at %. The compositional ratio of the buffer layer 4 is Co:Fe:B:Ta=37:35:18:10. The atomic radius of Co is 118 Å, the atomic radius of Fe is 124 Å, the atomic radius of B is 84 Å, and the atomic radius of Ta is 158 Å. The MR ratio of the magneto resistive element 10 according to Comparative Example 1 was 7.2%.

The buffer layer 4 of Comparative Example 2 contains Fe, Cu, and Ni as main components. The buffer layer 4 does not contain Co as the main component. The compositional ratio of the buffer layer 4 is Fe:Cu:Ni=35:35:30. The atomic radius of Fe is 124 Å, the atomic radius of Cu is 122 Å, and the atomic radius of Ni is 117 Å. The buffer layer 4 of Comparative Example 2 was crystallized immediately after film formation. The MR ratio of the magneto resistive element 10 according to Comparative Example 2 was 6.2%.

The results of Examples 1 to 8 and Comparative Examples 1 and 2 are summarized in Table 1 below.

TABLE 1

| | | | | | Atomic radius | | |
|---|---|---|---|---|---|---|---|
| | Buffer layer | | | | ratio (with first | | |
| | | | | Co | atom as reference) | | MR |
| | First | Second | Third | compositional | Second | Third | ratio |
| | atom | atom | atom | proportion | atom | atom | (%) |
| Example 1 | Fe | Si | Ru | 5 | 91.9% | 109.7% | 9.1 |
| Example 2 | Fe | Si | Ru | 5 | 91.9% | 109.7% | 10.5 |
| Example 3 | Cr | Ge | Mo | 5 | 92.3% | 112.3% | 14.3 |
| Example 4 | Cr | Si | Mo | 5 | 87.7% | 112.3% | 15.5 |
| Example 5 | Cr | Si | Zr | 5 | 87.7% | 126.2% | 17.0 |
| Example 6 | Au | Si | Ti | 5 | 87.7% | 113.8% | 19.6 |
| Example 7 | Au | Si | Zr | 5 | 87.7% | 126.2% | 21.1 |
| Example 8 | Au | B | Zr | 5 | 64.6% | 126.2% | 23.4 |
| Comparative | Fe | B | Ta | 37 | 67.7% | 127.4% | 7.2 |
| Example 1 | | | | | | | |
| Comparative | Cu | Ni | Fe | 5 | 96.0% | 101.6% | 6.2 |
| Example 2 | | | | | | | |

### EXPLANATION OF REFERENCES

1 First ferromagnetic layer
2 Second ferromagnetic layer
3 Nonmagnetic layer
4 Buffer layer
5 Buffer layer
8 Spin-orbit torque wiring
10 magneto resistive element
21 Resistance measuring device
22 Power supply
23 Measuring part
26 DC power supply
27 Inductor
28 Capacitor
29 Output port
30, 31 Wiring
100, 101, 102 Magnetic recording element
103 High frequency device

What is claimed is:

1. A magneto resistive element comprising:
a first ferromagnetic layer, a second ferromagnetic layer, a nonmagnetic layer, and a buffer layer,
wherein the nonmagnetic layer is between the first ferromagnetic layer and the second ferromagnetic layer,
wherein the buffer layer is in contact with the first ferromagnetic layer,
wherein the first ferromagnetic layer contains a Heusler alloy containing Co,
wherein the buffer layer contains at least a first atom, a second atom, and a third atom other than Co as main components,
wherein the buffer layer does not contain Co or contains Co at a proportion less than a compositional proportion of the first atom, the second atom, and the third atom, and
wherein, in a case where an atomic radius of any one atom of the first atom, the second atom, and the third atom is taken as a reference, an atomic radius of another atom thereof is 95% or less or 105% or more of the reference.

2. The magneto resistive element according to claim 1,
wherein the buffer layer contains Co, and
wherein a Co concentration at a center of the buffer layer in a thickness direction is lower than a Co concentration at an interface between the buffer layer and the first ferromagnetic layer.

3. The magneto resistive element according to claim 1, wherein the first atom, the second atom, and the third atom are nonmagnetic atoms.

4. The magneto resistive element according to claim 1, wherein the first atom, the second atom, and the third atom are different from atoms constituting the Heusler alloy.

5. The magneto resistive element according to claim 1, wherein the first atom, the second atom, and the third atom belong to different periods in the periodic table.

6. The magneto resistive element according to claim 1, wherein the first atom, the second atom, and the third atom belong to different groups in the periodic table.

7. The magneto resistive element according to claim 1,
wherein the first atom belongs to any one of Group 4, Group 5, and Group 6 in the periodic table,
wherein the second atom belongs to Group 11 in the periodic table, and
wherein the third atom belongs to Group 13 or Group 14 in the periodic table.

8. The magneto resistive element according to claim 1, wherein any one of the first atom, the second atom, and the third atom is a transition metal atom or a metalloid atom.

9. The magneto resistive element according to claim 1, wherein, in a case where an atomic radius of any one atom of the first atom, the second atom, and the third atom is taken as a reference, an atomic radius of another atom thereof is 90% or less or 110% or more of the reference.

10. The magneto resistive element according to claim 1, wherein, in a case where an atomic radius of any one atom of the first atom, the second atom, and the third atom is taken as a reference, an atomic radius of another atom thereof is 85% or less or 115% or more of the reference.
